(19) United States
(12) Patent Application Publication
(10) Pub. No.: US 2026/0150603 A1
(43) Pub. Date: May 28, 2026

(54) SUBSTRATE PROCESSING METHOD AND SUBSTRATE PROCESSING APPARATUS

(71) Applicant: Tokyo Electron Limited, Tokyo (JP)

(72) Inventors: Koji KAGAWA, Koshi City (JP); Ryo YAMAMOTO, Koshi City (JP); Hidemasa ARATAKE, Koshi City (JP)

(21) Appl. No.: 19/350,289

(22) Filed: Oct. 6, 2025

(30) Foreign Application Priority Data
Oct. 15, 2024 (JP) 2024-179915

(51) Int. Cl. H01L 21/311; H01L 21/67

(52) U.S. Cl. CPC H10P 50/28; H10P 72/0426

(57) ABSTRACT

A substrate processing method includes immersing a substrate in ozonated water; and heating the substrate by irradiating the substrate with light of a wavelength that is transmittable through the ozonated water while the substrate is immersed in the ozonated water.

### CROSS-REFERENCE TO RELATED APPLICATION

This application is based upon and claims the benefit of priority from Japanese Patent Application No. 2024-179915, filed on Oct. 15, 2024, the entire content of which is incorporated herein by reference.

### TECHNICAL FIELD

The present disclosure relates to a substrate processing method and a substrate processing apparatus.

### BACKGROUND

Conventionally, a technique is known in which a substrate such as a semiconductor wafer (hereinafter also referred to as “wafer”) is processed with ozonated water while being irradiated with ultraviolet light (see Patent Document 1).

### PRIOR ART DOCUMENT

### Patent Document

Patent Document 1: Japanese Laid-open Patent Publication No. 2002-280339

### SUMMARY

An embodiment of the present disclosure provides a substrate processing method including immersing a substrate in ozonated water and heating the substrate by irradiating the substrate with light of a wavelength that is transmittable through the ozonated water while the substrate is immersed in the ozonated water.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a configuration of a substrate processing apparatus according to an embodiment.

FIG. 2 is a cross-sectional view of a processing tank according to the embodiment as viewed from a positive X-axis direction to a negative X-axis direction.

FIG. 3 is a diagram illustrating an example of a relationship between wavelength (nm) of light emitted to a wafer from a light irradiator and light absorption rate (%) of the wafer.

FIG. 4 is a flowchart illustrating a sequence of substrate processing executed by the substrate processing apparatus according to the embodiment.

FIG. 5 is a flowchart illustrating a sequence of substrate processing executed by the substrate processing apparatus according to Modification 1 of the embodiment.

FIG. 6 is a flowchart illustrating a sequence of substrate processing executed by the substrate processing apparatus according to Modification 2 of the embodiment.

FIG. 7 is a cross-sectional view of the processing tank according to Modification 3 of the embodiment as viewed from the positive X-axis direction to the negative X-axis direction.

FIG. 8 is a flowchart illustrating a sequence of substrate processing executed by the substrate processing apparatus according to Modification 3 of the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment for implementing a substrate processing method and a substrate processing apparatus according to the present disclosure will be described in detail with reference to the drawings. In addition, the present disclosure is not limited by this embodiment. Further, it should be noted that the drawings are schematic, and the dimensional relationships and proportions of respective elements may differ from those in reality. Furthermore, the dimensional relationships and proportions between the drawings may also differ.

Further, in the embodiment described below, terms such as “constant”, “orthogonal”, “vertical”, or “parallel” may be used, but these terms do not necessarily indicate strict “constancy”, “orthogonality”, “perpendicularity”, or “parallelism”. That is, the above respective terms are intended to allow for deviations due to manufacturing precision, installation precision, and others.

Further, in the respective drawings referenced below, to enable easier understanding of descriptions, an orthogonal coordinate system may be defined, specifying mutually orthogonal X-axis direction, Y-axis direction, and Z-axis direction, with the positive Z-axis direction being the vertically upward direction. Further, the rotational direction about the vertical axis as the rotational center may be referred to as the θ-direction.

Conventionally, a technology is known in which a substrate such as a semiconductor wafer (hereinafter also referred to as “wafer”) is processed with ozonated water while being irradiated with ultraviolet light. However, in the above-described conventional technology, there is room for further improvement in efficiently processing the substrate with ozonated water.

Therefore, a technology capable of efficiently processing a substrate with ozonated water is desired to overcome the above-described issue.

### <Configuration of Substrate Processing Apparatus>

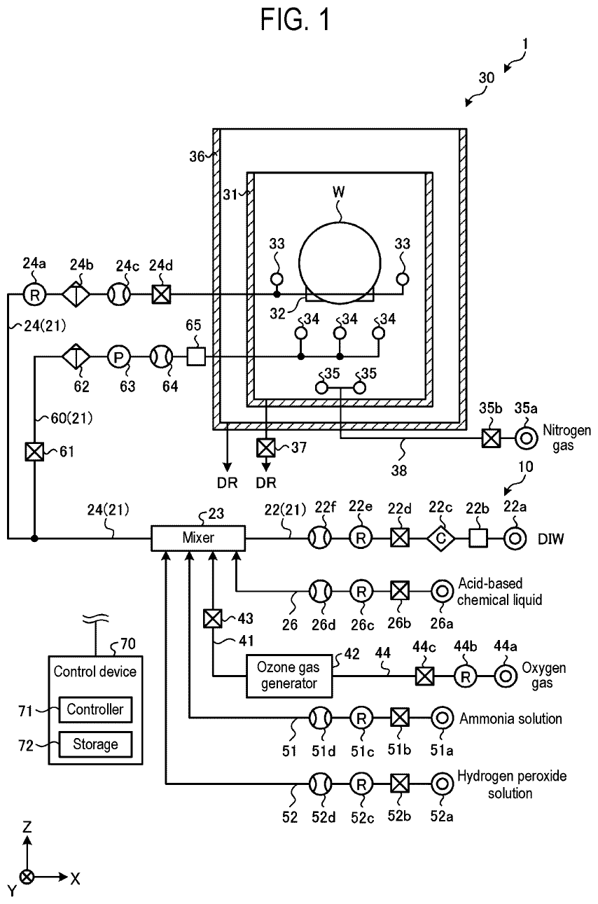

A configuration of a substrate processing apparatus according to an embodiment will be described with reference to FIG. 1. FIG. 1 is a diagram illustrating the configuration of a substrate processing apparatus according to the embodiment.

As illustrated in FIG. 1, the substrate processing apparatus 1 includes a processing liquid generator 10 and a substrate processor 30. The processing liquid generator 10 sequentially generates various processing liquids such as ozonated water, rinse liquid, and cleaning liquid. The substrate processor 30 performs, using the sequentially generated various processing liquids, a series of substrate processing, including ozonated water processing, rinsing, and cleaning for the wafer W, in a single processing tank 31.

Further, the substrate processing apparatus 1 includes a processing liquid supply path 21 provided from the processing liquid generator 10 to the substrate processor 30. The processing liquid supply path 21 connects a DIW source 22a of the processing liquid generator 10 to the substrate processor 30.

The processing liquid supply path 21 is configured by connecting a first supply path 22, a mixer 23, and a second supply path 24 in this order.

The first supply path 22 supplies a deionized water (DIW), which is a raw material for ozonated water, a DIW as a rinse liquid, and a DIW, which is a raw material for SC1 (an aqueous solution containing ammonia and hydrogen peroxide), as a cleaning liquid, to the mixer 23. The first supply path 22 includes, in order from an upstream side, the DIW source 22a, a degassing module 22b, a cooler 22c, a valve 22d, a constant pressure valve 22e, and a flow meter 22f.

The DIW source 22a is, for example, a tank that stores DIW. The degassing module 22b removes a dissolved gas such as a nitrogen gas dissolved in the DIW supplied from the DIW source 22a. By removing the dissolved gas contained in the DIW with the degassing module 22b, it is possible to efficiently dissolve an ozone gas in the DIW.

The cooler 22c cools the DIW flowing through the first supply path 22 to a desired temperature (e.g., 10 to 20 degrees C.). By cooling the DIW with the cooler 22c, it is possible to efficiently dissolve an ozone gas in the DIW.

The constant pressure valve 22e adjusts a flow rate of the DIW supplied to the mixer 23 based on a flow rate of the DIW measured by the flow meter 22f. That is, the constant pressure valve 22e performs feedback control based on the flow rate of the DIW measured by the flow meter 22f.

The mixer 23 is connected to the first supply path 22 on an upstream side and connected to the second supply path 24 on a downstream side. Further, an acid-based chemical liquid supply path 26 is connected to the mixer 23.

The acid-based chemical liquid supply path 26 supplies an acid-based chemical liquid such as an organic acid (e.g., citric acid and acetic acid), a hydrochloric acid, or a sulfuric acid to the mixer 23. In the embodiment, by supplying the acid-based chemical liquid to the DIW to adjust the pH of the DIW to be acidic, it is possible to increase a concentration of ozone dissolved in the DIW.

The acid-based chemical liquid supply path 26 includes, in order from an upstream side, an acid-based chemical liquid source 26a, a valve 26b, a constant pressure valve 26c, and a flow meter 26d. The acid-based chemical liquid source 26a is, for example, a cabinet or a circulation line capable of generating the acid-based chemical liquid.

The constant pressure valve 26c adjusts a flow rate of the acid-based chemical liquid supplied to the mixer 23 based on a flow rate of the acid-based chemical liquid measured by the flow meter 26d. That is, the constant pressure valve 26c performs feedback control based on the flow rate of the acid-based chemical liquid measured by the flow meter 26d.

An ozone gas supply path 41 is connected to the mixer 23 at a downstream side of a connection point between the acid-based chemical liquid supply path 26 and the mixer 23.

The ozone gas supply path 41 supplies an ozone gas to the mixer 23. The ozone gas supply path 41 includes, in order from an upstream side, an ozone gas generator 42 and a valve 43. In addition, a check valve may be provided between the valve 43 and the mixer 23.

The ozone gas generator 42 generates an ozone gas from an oxygen gas using a known technology. The oxygen gas, which is a raw material for the ozone gas, is supplied from an oxygen gas supply path 44 to the ozone gas generator 42. The oxygen gas supply path 44 includes, in order from an upstream side, an oxygen gas source 44a, a constant pressure valve 44b, and a valve 44c. The oxygen gas source 44a is, for example, a tank that stores the oxygen gas.

In addition, although not illustrated in FIG. 1, the ozone gas generator 42 is connected to a cooling water supply for supplying cooling water and a cooling water discharger for discharging the used cooling water.

An ammonia solution supply path 51 is connected to the mixer 23 at a downstream side of a connection point between the ozone gas supply path 41 and the mixer 23.

The ammonia solution supply path 51 supplies an ammonia solution, which is a raw material for SC1 as a cleaning liquid, to the mixer 23. The ammonia solution supply path 51 includes, in order from an upstream side, an ammonia solution source 51a, a valve 51b, a constant pressure valve 51c, and a flow meter 51d. The ammonia solution source 51a is, for example, a tank that stores the ammonia solution.

The constant pressure valve 51c adjusts a flow rate of the ammonia solution supplied to the mixer 23 based on a flow rate of the ammonia solution measured by the flow meter 51d. That is, the constant pressure valve 51c performs feedback control based on the flow rate of the ammonia solution measured by the flow meter 51d.

A hydrogen peroxide solution supply path 52 is connected to the mixer 23 at a downstream side of a connection point between the ammonia solution supply path 51 and the mixer 23.

The hydrogen peroxide solution supply path 52 supplies a hydrogen peroxide solution, which is a raw material for SC1 as a cleaning liquid, to the mixer 23. The hydrogen peroxide solution supply path 52 includes, in order from an upstream side, a hydrogen peroxide solution source 52a, a valve 52b, a constant pressure valve 52c, and a flow meter 52d. The hydrogen peroxide solution source 52a is, for example, a tank that stores the hydrogen peroxide solution.

The constant pressure valve 52c adjusts a flow rate of the hydrogen peroxide solution supplied to the mixer 23 based on a flow rate of the hydrogen peroxide solution measured by the flow meter 52d. That is, the constant pressure valve 52c performs feedback control based on the flow rate of the hydrogen peroxide solution measured by the flow meter 52d.

The mixer 23 selectively mixes other chemical liquids or gases with the DIW supplied from the first supply path 22 to sequentially generate various processing liquids. That is, the mixer 23 may generate ozonated water by mixing the DIW supplied from the first supply path 22, the acid-based chemical liquid supplied from the acid-based chemical liquid supply path 26, and the ozone gas supplied from the ozone gas supply path 41. Further, the mixer 23 may generate SC1 by mixing the DIW supplied from the first supply path 22, the ammonia solution supplied from the ammonia solution supply path 51, and the hydrogen peroxide solution supplied from the hydrogen peroxide solution supply path 52. Further, the mixer 23 may release the DIW supplied from the first supply path 22 to flow as a rinse liquid to the downstream side of the mixer 23 without mixing the DIW with other chemical liquids or gases. The second supply path 24 is connected to the downstream side of the mixer 23.

The second supply path 24 is provided between the mixer 23 of the processing liquid generator 10 and the substrate processor 30, and supplies various processing liquids supplied from the mixer 23 to a first nozzle 33 of the substrate processor 30, which will be described later. Specifically, the second supply path 24 sequentially supplies the ozonated water, the DIW as a rinse liquid, and the SC1 as a cleaning liquid to the first nozzle 33.

The second supply path 24 includes, in order from an upstream side, a constant pressure valve 24a, a filter 24b, a flow meter 24c, and a valve 24d. The constant pressure valve 24a adjusts a flow rate of a processing liquid flowing through the second supply path 24 based on a flow rate of the processing liquid measured by the flow meter 24c. That is, the constant pressure valve 24a performs feedback control based on the flow rate of the processing liquid measured by the flow meter 24c.

The filter 24b removes contaminants such as particles contained in various processing liquids flowing through the second supply path 24.

At an upstream side of the constant pressure valve 24a in the second supply path 24, a third supply path 60 branches off from the second supply path 24 and is connected to a second nozzle 34 of the substrate processor 30, which will be described later. The third supply path 60 supplies the ozonated water to the second nozzle 34.

The third supply path 60 includes, in order from an upstream side, a valve 61, a filter 62, a pump 63 (an example of a pressurizer), a flow meter 64, and a throttle valve 65. The filter 62 removes contaminants such as particles contained in the ozonated water flowing through the third supply path 60.

The pump 63 pressurizes the ozonated water flowing through the third supply path 60 to a desired pressure that is higher than the atmospheric pressure. The pressurized ozonated water is supplied to the second nozzle 34 via the third supply path 60. As described above, by pressurizing the ozonated water, it is possible to efficiently generate ozonated water having a desired ozone concentration.

This is because a molar fraction M of ozone gas dissolved in the raw material liquid, DIW is estimated to follow Henry's law which is represented in the following equation (1). According to Henry's law, the molar fraction M of dissolved ozone gas is proportional to a partial pressure P of ozone in the gas.

$$M = {H}^{- 1} \cdot P \qquad ( 1 )$$

H: Henry's constant

Here, the above-mentioned “desired ozone concentration” refers, for example, to an ozone concentration capable of removing (peeling) a resist film formed on the wafer W, and is, for example, 10 ppm or more and 200 ppm or less. Further, the above-mentioned “desired pressure” refers, for example, to a pressure capable of maintaining the ozone concentration of the ozonated water at the desired ozone concentration, and is, for example, in a range of 0.6 MPa to 2.0 MPa.

The throttle valve 65 is provided at a downstream side of the pump 63 in the third supply path 60 and adjusts the pressure of ozonated water pressurized by the pump 63.

The substrate processor 30 includes the processing tank 31, a substrate holder 32, the first nozzle 33, the second nozzle 34 (an example of an ozonated water supply nozzle), a third nozzle 35 (an example of a gas supply nozzle), and a liquid sump 36.

The processing tank 31 is a box-shaped tank that is open at the top and sequentially stores various processing liquids in an interior of the processing tank 31. That is, the processing tank 31 sequentially stores the ozonated water, the DIW as a rinse liquid, and the SC1 as a cleaning liquid. A single wafer W is immersed in the processing liquid stored in the processing tank 31. Since the processing tank 31 is open at the top, the wafer W may be easily transported to the interior of the processing tank 31.

Further, the processing tank 31 is connected to a drain DR via a valve 37. Thus, when switching each processing liquid used in the ozonated water processing, rinsing, and cleaning of the wafer W, a controller 71 may control the valve 37 to discharge each processing liquid used in the ozonated water processing, rinsing, and cleaning to the drain DR.

The liquid sump 36 is disposed outside the processing tank 31 to surround the processing tank 31. The liquid sump 36 is a container that receives the processing liquid flowing out from an opening of the processing tank 31. The liquid sump 36 is connected to the drain DR and is capable of discharging the processing liquid flowing out from the opening of the processing tank 31 to the drain DR.

The substrate holder 32 holds a single wafer W in an upright posture. The substrate holder 32 is fixed in the interior of the processing tank 31 to hold the wafer W at an immersion position at which the entire wafer W is immersed in the processing liquid. The substrate holder 32 may receive a single wafer W from a substrate transport device (not illustrated) that transports the single wafer W and place it at the immersion position.

The first nozzle 33 is positioned in the interior of the processing tank 31 and supplies the ozonated water, the DIW as a rinse liquid, or the SC1 as a cleaning liquid to the processing tank 31. The first nozzle 33 extends along a thickness direction (Y-axis direction) of a single wafer W and discharges the ozonated water, the DIW as a rinse liquid, or the SC1 as a cleaning liquid from a plurality of discharge ports provided along the thickness direction of the single wafer W.

The first nozzle 33 is connected to the second supply path 24 of the processing liquid supply path 21 and discharges the ozonated water, the DIW as a rinse liquid, or the SC1 as a cleaning liquid supplied from the second supply path 24 from the plurality of discharge ports.

The first nozzle 33 may supply the ozonated water to the processing tank 31 at a higher flow rate than that of the ozonated water that the second nozzle 34 supplies to the processing tank 31. Therefore, the discharge ports of the first nozzle 33 have a larger opening diameter than those of the second nozzle 34.

The second nozzle 34 is positioned in the interior of the processing tank 31 below the first nozzle 33 and supplies pressurized ozonated water to the processing tank 31. The second nozzle 34 extends along the thickness direction (Y-axis direction) of a single wafer W and discharges the pressurized ozonated water from a plurality of discharge ports provided along the thickness direction of the single wafer W.

The second nozzle 34 is connected to the third supply path 60 of the processing liquid supply path 21 and discharges the pressurized ozonated water supplied from the third supply path 60 from a plurality of discharge ports.

The third nozzle 35 is positioned in the interior of the processing tank 31 below the second nozzle 34 and supplies a gas (e.g., nitrogen gas) to the ozonated water stored in the processing tank 31. For example, the third nozzle 35 discharges gas bubbles into the ozonated water stored in the processing tank 31. The third nozzle 35 extends along the thickness direction (Y-axis direction) of a single wafer W and discharges the gas from a plurality of discharge ports provided along the thickness direction of the single wafer W.

The third nozzle 35 is connected to a gas source 35a via a gas supply path 38. A valve 35b is provided in the gas supply path 38. The third nozzle 35 discharges a gas (e.g., nitrogen gas) supplied from the gas source 35a through a plurality of discharge ports. For example, the third nozzle 35 discharges gas bubbles upward into the ozonated water stored in the processing tank 31 to form an upward flow of the ozonated water inside the processing tank 31.

The substrate processing apparatus 1 according to the embodiment may supply a rapid flow of ozonated water to a surface of a single wafer W located in the interior of the processing tank 31 by discharging the gas from the third nozzle 35. This may improve the removability of the resist film formed on the surface of the wafer W. In addition, the gas discharged from the third nozzle 35 is not limited to nitrogen gas, and may be, for example, at least one of nitrogen gas, oxygen gas, ozone gas, or air.

Further, the substrate processing apparatus 1 further includes a control device 70. The control device 70 controls operations of each component of the substrate processing apparatus 1. The control device 70 is, for example, a computer and includes the controller 71 and a storage 72.

The controller 71 is realized, for example, by executing various programs stored in an internal storage of the control device 70 using a Central Processing Unit (CPU) or a Micro Processing Unit (MPU), with Random Access Memory (RAM) as a work area. Further, the controller 71 may be realized, for example, by an integrated circuit such as an Application Specific Integrated Circuit (ASIC) or a Field Programmable Gate Array (FPGA).

The controller 71 includes a non-transitory computer readable storage medium. The non-transitory computer readable storage medium stores programs that control various types of processing executed in the substrate processing apparatus 1. The programs may originally be stored in the non-transitory computer readable storage medium, and may be installed from another non-transitory computer readable storage medium into the non-transitory computer readable storage medium of the controller 71. Examples of the non-transitory computer readable storage medium may include a hard disk (HD), a flexible disk (FD), a compact disk (CD), a magneto-optical disk (MO), and a memory card.

The storage 72 is realized, for example, by a semiconductor memory device such as a RAM or a flash memory, or by a storage device such as a hard disk or an optical disk.

### <Configuration of Light Irradiator>

The processing tank 31 is provided with a light irradiator that irradiates the wafer W with light. Here, a conventional technology of processing a wafer with ozonated water while irradiating the wafer with ultraviolet light is known.

However, in the above-described technology, the ultraviolet light emitted to the wafer is absorbed by the ozonated water, causing a risk of increasing the temperature of the ozonated water. An increase in the temperature of the ozonated water is considered to promote decomposition and loss of activity of ozone, leading to a reduction in the ozone concentration in the ozonated water.

In view of this, the substrate processing apparatus 1 according to the embodiment is configured to heat the wafer W by irradiating the wafer W with light of a wavelength that is transmittable through ozonated water, using the light irradiator provided on the processing tank 31. This may prevent the increase in the temperature of ozonated water, compared to the case in which the wafer W is irradiated with ultraviolet light. This enables heating the wafer W to a desired temperature while preventing a reduction in ozone concentration caused by the temperature increase of ozonated water. As a result, according to the substrate processing apparatus 1 of the embodiment, it is possible to efficiently process the wafer W with ozonated water.

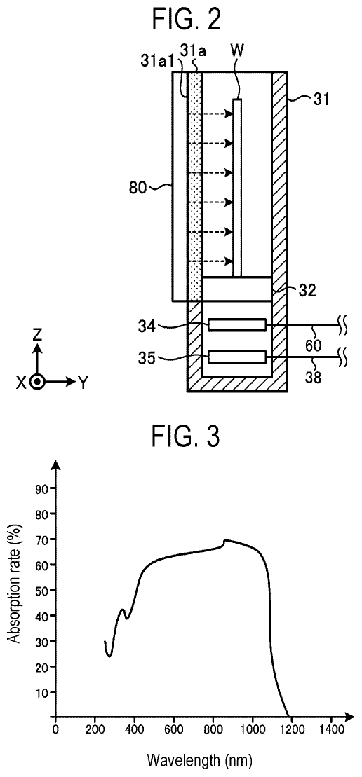

A configuration of the processing tank 31 and a light irradiator will be described with reference to FIG. 2. FIG. 2 is a cross-sectional view of the processing tank 31 according to the embodiment as viewed from the positive X-axis direction to the negative X-axis direction. In addition, for ease of understanding, the first nozzle 33 is omitted in FIG. 2.

As illustrated in FIG. 2, the processing tank 31 is provided with a light irradiator 80. The light irradiator 80 is a light source such as a light emitting diode (LED). The light irradiator 80 is oriented relative to the processing tank 31 so as to face a main surface of the wafer W. The main surface of the wafer W is, for example, the surface of the wafer W on which the resist film is formed. The light irradiator 80 may be oriented relative to the processing tank 31 so as to face at least one of the main surface of the wafer W or a back surface opposite to the main surface. The light irradiator 80 irradiates the wafer W with light of a wavelength that is transmittable through ozonated water.

FIG. 3 is a diagram illustrating an example of a relationship between the wavelength (nm) of light emitted to the wafer W from the light irradiator 80 and the light absorption rate (%) of the wafer W. As illustrated in FIG. 3, when the wavelength of light emitted to the wafer W from the light irradiator 80 is 350 nm or more and 1100 nm or less, the light absorption rate of the wafer W may be increased to approximately 40% or more. However, when the wavelength of light emitted to the wafer W from the light irradiator 80 exceeds 600 nm, the light absorption rate of ozonated water increases, leading to an increase in the temperature of the ozonated water around the wafer W. Therefore, from the viewpoint of selectively heating the surface of the wafer W while preventing the temperature increase of the ozonated water around the wafer W, it is desirable for the wavelength of the light emitted to the wafer W from the light irradiator 80 to be 350 nm or more and 600 nm or less. Hereinafter, light having a wavelength of 350 nm or more and 600 nm or less is referred to as “specific wavelength light”. The light irradiator 80 irradiates the wafer W with specific wavelength light.

A description will be made by returning to FIG. 2. The processing tank 31 has a light transmitter 31a provided on one of two sidewalls facing the main surface and back surface of the wafer W. The light transmitter 31a is in contact with ozonated water and transmits specific wavelength light. The light transmitter 31a is made of a material that is capable of transmitting specific wavelength light and has high corrosion resistance against the processing liquids such as ozonated water. The corrosion resistance of the light transmitter 31a against the processing liquids such as ozonated water is higher than that of other portions of the processing tank 31. For example, quartz may be used as a material forming the light transmitter 31a. The light irradiator 80 is disposed on an outer surface 31a1 of the light transmitter 31a, which is opposite to an inner surface in contact with the ozonated water.

As described above, disposing the light irradiator 80 on the outer surface 31al of the light transmitter 31a provided on one of two sidewalls of the processing tank 31 facing the main surface and back surface of the wafer W, enables efficient irradiation of the main surface of the wafer W with specific wavelength light from the light irradiator 80. Therefore, it is possible to efficiently heat the main surface of the wafer W.

### <Substrate Processing Sequence>

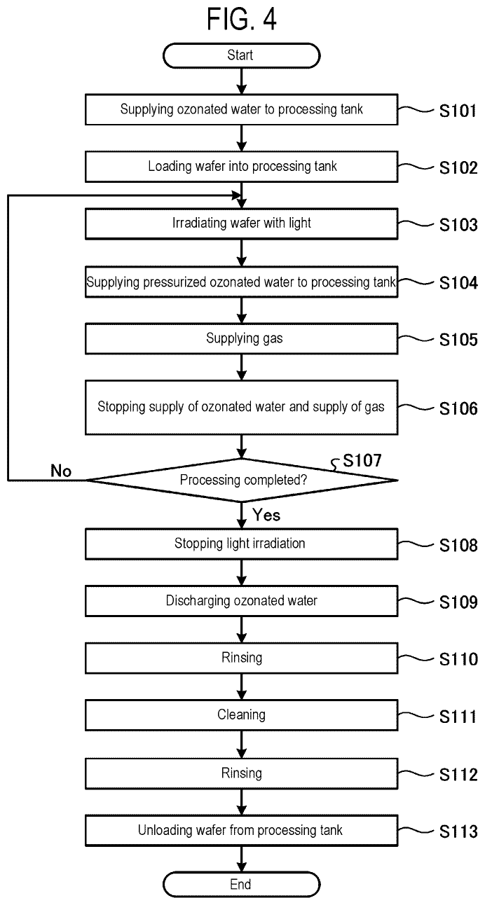

Next, a sequence of substrate processing according to the embodiment will be described with reference to FIG. 4. FIG. 4 is a flowchart illustrating the sequence of substrate processing executed by the substrate processing apparatus 1 according to the embodiment. Each processing sequence illustrated in FIG. 4 is executed under the control of the controller 71.

Before the start of a series of substrate processing illustrated in FIG. 4, no processing liquid is stored in the processing tank 31. That is, the processing tank 31 is in an empty state before the start of a series of substrate processing.

As illustrated in FIG. 4, the substrate processing apparatus 1 first supplies ozonated water from the first nozzle 33 (step S101). Specifically, the controller 71 controls the processing liquid generator 10 to open the valves 22d, 24d, 26b, 43 and 44c so that ozonated water generated in the mixer 23 is supplied to the first nozzle 33 via the second supply path 24. Then, the ozonated water is discharged from the discharge ports of the first nozzle 33 into the processing tank 31 and stored in the processing tank 31. The controller 71 controls the processing liquid generator 10 to close the valves 22d, 24d, 26b, 43 and 44c after a predetermined time has passed. This stops the supply of ozonated water from the first nozzle 33.

Subsequently, the substrate processing apparatus 1 loads the wafer W into the processing tank 31 (step S102). Specifically, the controller 71 controls a substrate transport device (not illustrated) that transports the wafer W, to deliver the wafer W to and from the substrate holder 32 placed inside the processing tank 31. Thus, the wafer W is positioned at the immersion position inside the processing tank 31. That is, the wafer W is immersed in the ozonated water stored in the processing tank 31.

Subsequently, the controller 71 controls the light irradiator 80 to irradiate the wafer W with light of a wavelength that is transmittable through ozonated water, that is, specific wavelength light, and therefore heats the wafer W to a desired temperature (step S103).

In the embodiment, the wafer W is heated by irradiating the wafer W with specific wavelength light while the wafer W is immersed in ozonated water. This enables the wafer W to be heated to a desired temperature while preventing a reduction in ozone concentration caused by the temperature increase of ozonated water. As a result, according to the substrate processing apparatus 1 of the embodiment, it is possible to efficiently process the wafer W with ozonated water.

Subsequently, the substrate processing apparatus 1 supplies pressurized ozonated water from the second nozzle 34 (step S104). Specifically, the controller 71 controls the processing liquid generator 10 to open the valves 22d, 26b, 43, 44c and 61, and simultaneously controls the pump 63 to pressurize the ozonated water flowing through the third supply path 60. Thus, the ozonated water generated in the mixer 23 is pressurized in the third supply path 60, and the pressurized ozonated water is supplied to the second nozzle 34 via the third supply path 60. Then, the pressurized ozonated water is discharged from the discharge ports of the second nozzle 34 into the processing tank 31, and therefore, the ozonated water stored in the processing tank 31 is pressurized.

As described above, in the embodiment, the wafer W is heated by being irradiated with specific wavelength light while pressurized ozonated water is being supplied to the processing tank 31. This enables the wafer W to be heated while preventing a reduction in ozone concentration in the ozonated water around the wafer W caused by a pressure reduction in the ozonated water inside the processing tank 31.

That is, in the embodiment, by increasing the pressure of the ozonated water inside the processing tank 31, the ozone concentration in the ozonated water around the wafer W may be maintained, and therefore it is possible to efficiently process the wafer W with ozonated water.

Further, in the embodiment, the pressure of ozonated water pressurized by the pump 63 is adjusted using the throttle valve 65 provided at the downstream side of the pump 63 in an ozonated water supply path (the third supply path 60) toward the second nozzle 34. Thus, the pressure of ozonated water immediately before being supplied into the processing tank 31 from the second nozzle 34 may be maintained, and therefore it is possible to efficiently process the wafer W with ozonated water.

Subsequently, the substrate processing apparatus 1 supplies a gas from the third nozzle 35 (step S105). Specifically, the controller 71 opens the valve 35b, and gas bubbles are discharged from the third nozzle 35 into the ozonated water stored in the processing tank 31.

As described above, in the embodiment, it is possible to supply a rapid flow of ozonated water to the surface of a single wafer W located in the interior of the processing tank 31 by discharging gas from the third nozzle 35. This may improve the removability of the resist film from the surface of the wafer W.

Subsequently, the controller 71 stops the supply of ozonated water from the second nozzle 34 and the supply of gas from the third nozzle 35 (step S106).

Subsequently, the controller 71 determines whether the ozonated water processing of the wafer W has been completed (step S107). For example, the controller 71 may complete the ozonated water processing of the wafer W when the number of repetitions of the processing in steps S103 to S106 reaches a predetermined number.

If it is determined in step S107 that the ozonated water processing of the wafer W has not been completed (step S107 “No”), the controller 71 returns the processing to step S103 and continues the ozonated water processing.

On the other hand, if it is determined that the ozonated water processing of the wafer W has been completed (step S107 “Yes”), the controller 71 stops the irradiation of the wafer W with specific wavelength light (step S108).

Then, the controller 71 opens the valve 37 for a predetermined time to discharge the ozonated water from the processing tank 31 (step S109).

Subsequently, the substrate processing apparatus 1 performs rinsing of the wafer W (step S110). Specifically, the controller 71 opens the valves 22d and 24d, so that DIW as a rinse liquid is stored in the processing tank 31, and the wafer W is immersed in the DIW. Therefore, the ozonated water is removed from the wafer W.

Then, the controller 71 closes the valves 22d and 24d, and opens the valve 37 for a predetermined time to discharge the DIW from the processing tank 31.

Subsequently, the substrate processing apparatus 1 performs cleaning of the wafer W (step S111). Specifically, the controller 71 opens the valves 22d, 24d, 51b and 52b so that SC1 as a cleaning liquid is stored in the processing tank 31, and the wafer W is immersed in the SC1. Therefore, impurities such as particles are removed from the wafer W.

Then, the controller 71 closes the valves 22d, 24d, 51b and 52b, and opens the valve 37 for a predetermined time to discharge the SC1 from the processing tank 31.

Subsequently, the substrate processing apparatus 1 performs rinsing of the wafer W (step S112). Specifically, the controller 71 opens the valves 22d and 24d so that DIW as a rinse liquid is stored in the processing tank 31, and the wafer W is immersed in the DIW. Therefore, the SC1 is removed from the wafer W.

Subsequently, the controller 71 controls the substrate transport device (not illustrated) to unload the wafer W from the processing tank 31 (step S113), and therefore completes the series of substrate processing.

### Modification 1

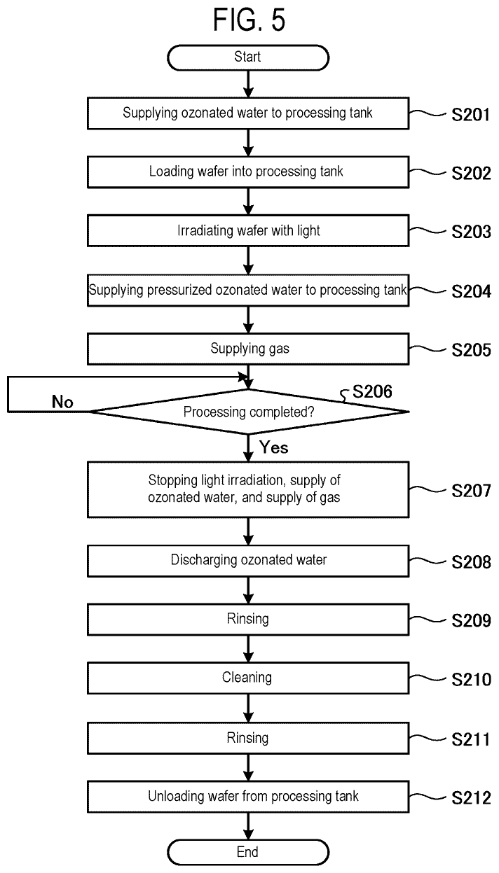

Next, various modifications of the substrate processing apparatus 1 according to the embodiment will be described with reference to FIGS. 5 to 8. FIG. 5 is a flowchart illustrating a sequence of substrate processing executed by the substrate processing apparatus 1 according to Modification 1 of the embodiment. In addition, a description of a configuration of the substrate processing apparatus 1 according to Modification 1 is omitted here, since the configuration is the same as that of the embodiment.

Before the start of a series of substrate processing illustrated in FIG. 5, no processing liquid is stored in the processing tank 31. That is, the processing tank 31 is in an empty state before the start of a series of substrate processing.

As illustrated in FIG. 5, the substrate processing apparatus 1 first supplies ozonated water from the first nozzle 33 (step S201). Specifically, the controller 71 controls the processing liquid generator 10 to open the valves 22d, 24d, 26b, 43 and 44c so that the ozonated water generated in the mixer 23 is supplied to the first nozzle 33 via the second supply path 24. Then, the ozonated water is discharged from the discharge ports of the first nozzle 33 into the processing tank 31 and stored in the processing tank 31. The controller 71 controls the processing liquid generator 10 to close the valves 22d, 24d, 26b, 43 and 44c after a predetermined time has passed. Thus, the supply of ozonated water from the first nozzle 33 is stopped.

Subsequently, the substrate processing apparatus 1 loads the wafer W into the processing tank 31 (step S202). Specifically, the controller 71 controls a substrate transport device (not illustrated) that transports the wafer W, to deliver the wafer W to and from the substrate holder 32 placed in the processing tank 31. Thus, the wafer W is positioned at an immersion position inside the processing tank 31. That is, the wafer W is immersed in the ozonated water stored in the processing tank 31.

Subsequently, the controller 71 controls the light irradiator 80 to irradiate the wafer W with light of a wavelength that is transmittable through ozonated water, that is, specific wavelength light, and therefore heats the wafer W to a desired temperature (step S203).

In Modification 1, the wafer W is heated by irradiating the wafer W with specific wavelength light while the wafer W is immersed in ozonated water. This enables the wafer W to be heated to a desired temperature while preventing a reduction in ozone concentration caused by the temperature increase of ozonated water. As a result, according to the substrate processing apparatus 1 of Modification 1, it is possible to efficiently process the wafer W with ozonated water.

Subsequently, the substrate processing apparatus 1 supplies pressurized ozonated water from the second nozzle 34 (step S204). Specifically, the controller 71 controls the processing liquid generator 10 to open the valves 22d, 26b, 43, 44c and 61, and simultaneously controls the pump 63 to pressurize the ozonated water flowing through the third supply path 60. Thus, the ozonated water generated in the mixer 23 is pressurized in the third supply path 60, and the pressurized ozonated water is supplied to the second nozzle 34 via the third supply path 60. Then, the pressurized ozonated water is discharged from the discharge ports of the second nozzle 34 into the processing tank 31, and therefore, the ozonated water stored in the processing tank 31 is pressurized.

As described above, in Modification 1, the wafer W is heated by being irradiated with specific wavelength light while pressurized ozonated water is being supplied to the processing tank 31. This enables the wafer W to be heated while preventing a reduction in ozone concentration in the ozonated water around the wafer W caused by a pressure reduction in the ozonated water inside the processing tank 31.

That is, in Modification 1, by increasing the pressure of ozonated water inside the processing tank 31, the ozone concentration in the ozonated water around the wafer W may be maintained, and therefore it is possible to process the wafer W more efficiently with the ozonated water.

Further, in Modification 1, the pressure of ozonated water pressurized by the pump 63 is adjusted using the throttle valve 65 provided at the downstream side of the pump 63 in an ozonated water supply path (the third supply path 60) toward the second nozzle 34. Thus, the pressure of ozonated water immediately before being supplied into the processing tank 31 from the second nozzle 34 may be maintained, and therefore it is possible to efficiently process the wafer W with ozonated water.

Subsequently, the substrate processing apparatus 1 supplies a gas from the third nozzle 35 (step S205). Specifically, the controller 71 opens the valve 35b and gas bubbles are discharged from the third nozzle 35 into the ozonated water stored in the processing tank 31.

As described above, in Modification 1, it is possible to supply a rapid flow of ozonated water to the surface of a single wafer W located in the interior of the processing tank 31 by discharging the gas from the third nozzle 35. This may improve the removability of the resist film from the surface of the wafer W.

Subsequently, the controller 71 determines whether the ozonated water processing of the wafer W has been completed (step S206). For example, the controller 71 may complete the ozonated water processing of the wafer W when a predetermined time has passed since the wafer W was loaded into the processing tank 31 in step S202.

If it is determined in step S206 that the ozonated water processing of the wafer W has not been completed (step S206 “No”), the controller 71 returns the processing to step S206 and continues the ozonated water processing.

On the other hand, if it is determined that the ozonated water processing of the wafer W has been completed (step S206 “Yes”), the controller 71 stops the irradiation of the wafer W with specific wavelength light, the supply of ozonated water from the second nozzle 34, and the supply of gas from the third nozzle 35 (step S207).

Then, the controller 71 opens the valve 37 for a predetermined time to discharge the ozonated water from the processing tank 31 (step S208).

Subsequently, the substrate processing apparatus 1 performs rinsing of the wafer W (step S209). Specifically, the controller 71 opens the valves 22d and 24d so that DIW as a rinse liquid is stored in the processing tank 31, and the wafer W is immersed in the DIW. Therefore, the ozonated water is removed from the wafer W.

Then, the controller 71 closes the valves 22d and 24d, and opens the valve 37 for a predetermined time to discharge the DIW from the processing tank 31.

Subsequently, the substrate processing apparatus 1 performs cleaning of the wafer W (step S210). Specifically, the controller 71 opens the valves 22d, 24d, 51b and 52b so that SC1 as a cleaning liquid is stored in the processing tank 31, and the wafer W is immersed in the SC1. Therefore, impurities such as particles are removed from the wafer W.

Then, the controller 71 closes the valves 22d, 24d, 51b and 52b, and opens the valve 37 for a predetermined time to discharge the SC1 from the processing tank 31.

Subsequently, the substrate processing apparatus 1 performs rinsing of the wafer W (step S211). Specifically, the controller 71 opens the valves 22d and 24d so that DIW as a rinse liquid is stored in the processing tank 31, and the wafer W is immersed in the DIW. Therefore, the SC1 is removed from the wafer W.

Subsequently, the controller 71 controls the substrate transport device (not illustrated) to unload the wafer W from the processing tank 31 (step S212), and therefore completes the series of substrate processing.

### Modification 2

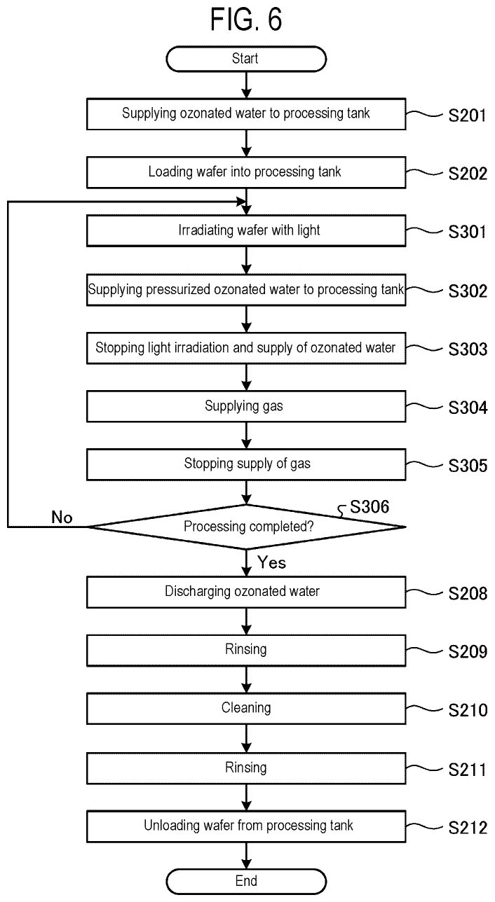

FIG. 6 is a flowchart illustrating a sequence of substrate processing executed by the substrate processing apparatus 1 according to Modification 2 of the embodiment. In addition, a description of a configuration of the substrate processing apparatus 1 according to Modification 2 is omitted here, since the configuration is the same as that of the embodiment. Further, in Modification 2, the same reference numerals are given to the same processing as those in Modification 1, and detailed descriptions of the same processing are omitted.

As illustrated in FIG. 6, the substrate processing apparatus 1 first supplies ozonated water from the first nozzle 33 (step S201). Subsequently, the substrate processing apparatus 1 loads the wafer W into the processing tank 31 (step S202).

Subsequently, the controller 71 controls the light irradiator 80 to irradiate the wafer W with light of a wavelength that is transmittable through ozonated water, that is, specific wavelength light, and therefore heats the wafer W to a desired temperature (step S301).

Subsequently, the substrate processing apparatus 1 supplies pressurized ozonated water from the second nozzle 34 (step S302). Then, the controller 71 stops the irradiation of the wafer W with specific wavelength light and the supply of ozonated water from the second nozzle 34 (step S303).

Subsequently, the substrate processing apparatus 1 supplies a gas from the third nozzle 35 (step S304). Then, the controller 71 stops the supply of gas from the third nozzle 35 (step S305).

Subsequently, the controller 71 determines whether the ozonated water processing of the wafer W has been completed (step S306). For example, the controller 71 may complete the ozonated water processing of the wafer W when a predetermined time has passed since the wafer W was loaded into the processing tank 31 in step S202.

If it is determined in step S306 that the ozonated water processing of the wafer W has not been completed (step S306 “No”), the controller 71 returns the processing to step S301.

On the other hand, if it is determined that the ozonated water processing of the wafer W has been completed (step S306 “Yes”), the controller 71 opens the valve 37 for a predetermined time to discharge the ozonated water from the processing tank 31 (step S208).

In the substrate processing according to Modification 2, after heating the wafer W by irradiating the wafer W with specific wavelength light during the ozonated water processing of the wafer W, a gas is supplied to the ozonated water. After the supply of gas to the ozonated water is stopped, the wafer W is heated again by being irradiated with specific wavelength light. That is, in the substrate processing according to Modification 2, the heating of the wafer W by specific wavelength light and the supply of gas to the ozonated water are repeated during the ozonated water processing of the wafer W.

As described above, the ozonated water processing may be performed by repeatedly using the wafer heated to high temperature and the ozonated water having high fluidity. Therefore, according to Modification 2, it is possible to more efficiently process the wafer W with ozonated water.

### Modification 3

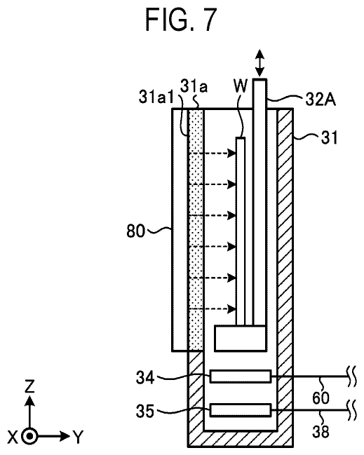

FIG. 7 is a cross-sectional view of the processing tank 31 according to Modification 3 of the embodiment as viewed from the positive X-axis direction to the negative X-axis direction. In addition, for ease of understanding, the first nozzle 33 is omitted in FIG. 7.

As illustrated in FIG. 7, in the substrate processing apparatus 1 according to Modification 3, the substrate processor 30 includes a substrate holder 32A instead of the substrate holder 32.

The substrate holder 32A holds a single wafer W. The substrate holder 32A is configured to move up and down relative to the processing tank 31, and is capable of holding and moving a single wafer W between a standby position above the processing tank 31 and an immersion position in the interior of the processing tank 31. At the immersion position, the entire wafer W is immersed in the processing liquid. The substrate holder 32A may receive the wafer W from a substrate transport device (not illustrated) that transports a single wafer W to the standby position, and may move the received wafer W down from the standby position to the immersion position to place the wafer W at the immersion position.

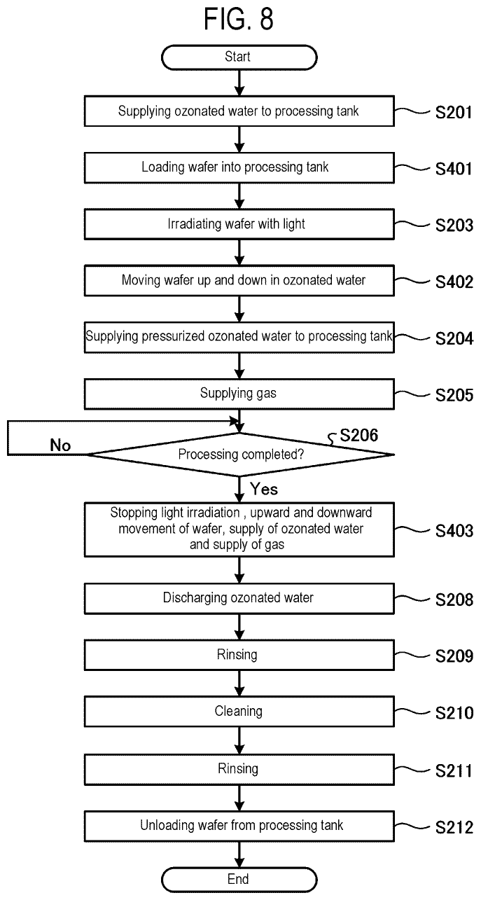

FIG. 8 is a flowchart illustrating a sequence of substrate processing executed by the substrate processing apparatus 1 according to Modification 3 of the embodiment. Further, in Modification 3, the same reference numerals are given to the same processing as those in Modification 1, and detailed descriptions of the same processing are omitted.

As illustrated in FIG. 8, the substrate processing apparatus 1 first supplies ozonated water from the first nozzle 33 (step S201).

Subsequently, the substrate processing apparatus 1 loads the wafer W into the processing tank 31 (step S401). Specifically, the controller 71 controls the substrate holder 32A to move the wafer W down from the standby position toward the immersion position, so that the wafer W is immersed in the ozonated water stored in the processing tank 31.

Subsequently, the controller 71 controls the light irradiator 80 to irradiate the wafer W with light of a wavelength that is transmittable through ozonated water, that is, specific wavelength light, and therefore heats the wafer W to a desired temperature (step S203).

Subsequently, the controller 71 controls the substrate holder 32A to move the wafer W up and down in the ozonated water (step S402).

As described above, in Modification 3, the wafer W is moved up and down in the ozonated water while being irradiated with specific wavelength light to heat the wafer W. Thus, it is possible to form a liquid flow of ozonated water in a vicinity of the surface of a single wafer W located in the interior of the processing tank 31. This may improve the removability of the resist film from the surface of the wafer W.

Next, the substrate processing apparatus 1 supplies pressurized ozonated water from the second nozzle 34 (step S204). Then, the substrate processing apparatus 1 supplies a gas from the third nozzle 35 (step S205).

Subsequently, the controller 71 determines whether the ozonated water processing of the wafer W has been completed (step S206). For example, the controller 71 may complete the ozonated water processing of the wafer W when a predetermined time has passed since the wafer W was loaded into the processing tank 31 in step S401.

If it is determined in step S206 that the ozonated water processing of the wafer W has not been completed (step S206 “No”), the controller 71 returns the processing to step S206 and continues the ozonated water processing.

On the other hand, if it is determined that the ozonated water processing of the wafer W has been completed (step S206 “Yes”), the controller 71 stops the irradiation of the wafer W with specific wavelength light, the upward and downward movement of the wafer W, the supply of ozonated water from the second nozzle 34, and the supply of gas from the third nozzle 35 (step S403).

As described above, a substrate processing method according to the embodiment includes an immersing step (for example, steps S102, S202, S401) and a heating step (steps S103, S203, S301). In the immersing step, a substrate (e.g., wafer W) is immersed in ozonated water. In the heating step, the substrate is heated by irradiating the substrate with light of a wavelength that is transmittable through ozonated water while the substrate is immersed in the ozonated water. This allows the substrate to be efficiently processed using the ozonated water.

Further, the wavelength of the light may be 350 nm or more and 600 nm or less. This enables selective heating of the surface of the substrate while preventing the temperature increase of the ozonated water around the substrate.

Further, the ozone concentration of the ozonated water may be 10 ppm or more and 200 ppm or less. This allows the substrate to be processed even more efficiently using the ozonated water.

Further, in the immersing step, the substrate may be immersed in ozonated water stored in a processing tank (for example, the processing tank 31) that is open at the top and performs processing by immersing the substrate in the ozonated water. This allows the substrate to be efficiently processed using the ozonated water stored in the processing tank.

Further, the heating step may be performed while moving the substrate up and down in the ozonated water stored in the processing tank. This allows the substrate to be processed even more efficiently using the ozonated water.

Further, the heating step may be performed while supplying pressurized ozonated water from an ozonated water supply nozzle (for example, the second nozzle 34) to the processing tank, using the ozonated water supply nozzle that supplies the ozonated water to the processing tank and a pressurizer (for example, the pump 63) that pressurizes the ozonated water at an upstream side of the ozonated water supply nozzle. This allows the substrate to be processed even more efficiently using the ozonated water.

Further, the heating step may be performed while supplying a gas into the ozonated water from a gas supply nozzle (for example, the third nozzle 35) that supplies the gas to the ozonated water stored in the processing tank. This allows the substrate to be processed even more efficiently using the ozonated water.

Further, a substrate processing apparatus (for example, the substrate processing apparatus 1) according to the embodiment includes a processing tank (for example, the processing tank 31), a light irradiator (for example, the light irradiator 80), and a controller (for example, the controller 71). The processing tank is open at the top and performs processing by immersing a substrate (for example, the wafer W) in ozonated water. The light irradiator is provided in the processing tank and is configured to irradiate the substrate with light of a wavelength that is transmittable through the ozonated water. The controller is configured to heat the substrate by immersing the substrate in the ozonated water stored in the processing tank, and irradiating the substrate with the light of the wavelength that is transmittable through the ozonated water using the light irradiator while the substrate is immersed in the ozonated water. This allows the substrate to be efficiently processed using the ozonated water.

Further, the processing tank may include a light transmitter (for example, the light transmitter 31a) that is in contact with the ozonated water and transmits the light, and that is provided on at least one of two sidewalls facing a main surface of the substrate or a back surface opposite to the main surface. The light irradiator may be disposed on an outer surface (for example, the outer surface 31al) opposite to an inner surface of the light transmitter that is in contact with the ozonated water. This enables efficient heating of the main surface of the substrate.

Further, the substrate processing apparatus may further include a substrate holder (for example, the substrate holder 32) that is fixed in an interior of the processing tank and is configured to hold the substrate at a position in which the substrate is immersed in the ozonated water. The controller may be configured to immerse the substrate in the ozonated water stored in the processing tank by controlling a substrate transport device that transports the substrate, to deliver the substrate to and from the substrate holder. This enables the substrate to be easily immersed in the ozonated water.

Further, the substrate processing apparatus may further include a substrate holder (for example, the substrate holder 32A) that holds the substrate and moves the substrate up and down between a standby position above the processing tank and an immersion position in an interior of the processing tank. The controller may be configured to immerse the substrate in the ozonated water stored in the processing tank by using the substrate holder to move the substrate down from the standby position to the immersion position, and to heat the substrate by irradiating the substrate with light using the light irradiator while moving the substrate up and down in the ozonated water using the substrate holder. This allows the substrate to be processed even more efficiently using the ozonated water.

Further, the substrate holder may hold a single substrate. This allows a single substrate held by the substrate holder to be processed efficiently using the ozonated water.

Further, the substrate processing apparatus may further include a gas supply nozzle (for example, the third nozzle 35) configured to supply a gas to the ozonated water stored in the processing tank. The controller may be configured to heat the substrate by irradiating the substrate with light using the light irradiator while supplying the gas to the ozonated water from the gas supply nozzle. This allows the substrate to be processed even more efficiently using the ozonated water.

Further, the gas supply nozzle may be positioned in an interior of the processing tank below the substrate. This allows the substrate to be processed even more efficiently using the ozonated water.

Further, the gas may be at least one of nitrogen gas, oxygen gas, ozone gas, or air. This allows the substrate to be processed even more efficiently using the ozonated water.

Further, the substrate processing apparatus may further include an ozonated water supply nozzle (for example, the second nozzle 34) configured to supply the ozonated water to the processing tank and a pressurizer (for example, the pump 63) configured to pressurize the ozonated water at an upstream side of the ozonated water supply nozzle. The controller may be configured to heat the substrate by irradiating the substrate with the light using the light irradiator while supplying the ozonated water pressurized by the pressurizer from the ozonated water supply nozzle to the processing tank. This allows the substrate to be processed even more efficiently using the ozonated water.

Further, the substrate processing apparatus may further include a throttle valve (for example, the throttle valve 65) provided at a downstream side of the pressurizer in an ozonated water supply path toward the ozonated water supply nozzle and configured to adjust a pressure of the ozonated water pressurized by the pressurizer. This allows the substrate to be processed even more efficiently using the ozonated water.

The embodiments disclosed herein are intended to be illustrative and not restrictive in all respects. In fact, the above embodiments may be implemented in various forms. Further, the above embodiments may be omitted, replaced, or modified in various ways without departing from the scope and spirit of the appended claims.

According to the present disclosure, it is possible to efficiently process a substrate with ozonated water.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method comprising:
immersing a substrate in ozonated water; and
heating the substrate by irradiating the substrate with light of a wavelength that is transmittable through the ozonated water while the substrate is immersed in the ozonated water.

2. The substrate processing method of claim 1, wherein the wavelength of the light is 350 nm or more and 600 nm or less.

3. The substrate processing method of claim 1, wherein an ozone concentration in the ozonated water is 10 ppm or more and 200 ppm or less.

4. The substrate processing method of claim 1, wherein in the immersing, the substrate is immersed in the ozonated water stored in a processing tank that is open at a top and in which a processing is performed by immersing the substrate in the ozonated water.

5. The substrate processing method of claim 4, wherein the heating is performed while moving the substrate up and down in the ozonated water stored in the processing tank.

6. The substrate processing method of claim 4, wherein the heating is performed while supplying pressurized ozonated water from an ozonated water supply nozzle to the processing tank using the ozonated water supply nozzle that supplies the ozonated water to the processing tank and a pressurizer that pressurizes the ozonated water at an upstream side of the ozonated water supply nozzle.

7. The substrate processing method of claim 4, wherein the heating is performed while supplying a gas to the ozonated water from a gas supply nozzle that supplies the gas to the ozonated water stored in the processing tank.

8. A substrate processing apparatus comprising:
a processing tank that is open at a top and in which a processing is performed by immersing a substrate in ozonated water;
a light irradiator provided on the processing tank and configured to irradiate the substrate with light of a wavelength that is transmittable through the ozonated water; and
a controller,
wherein the controller is configured to execute:
immersing the substrate in the ozonated water stored in the processing tank; and
heating the substrate by irradiating the substrate with the light of the wavelength that is transmittable through the ozonated water using the light irradiator while the substrate is immersed in the ozonated water.

9. The substrate processing apparatus of claim 8, wherein the processing tank includes a light transmitter that is in contact with the ozonated water and transmits the light, and that is provided on at least one of two sidewalls facing a main surface of the substrate or a back surface opposite to the main surface, and
wherein the light irradiator is disposed on an outer surface opposite to an inner surface of the light transmitter that is in contact with the ozonated water.

10. The substrate processing apparatus of claim 8, further comprising a substrate holder fixed in an interior of the processing tank and configured to hold the substrate at a position in which the substrate is immersed in the ozonated water,
wherein the controller is configured to execute the immersing the substrate in the ozonated water stored in the processing tank by controlling a substrate transport device that transports the substrate to deliver the substrate to and from the substrate holder.

11. The substrate processing apparatus of claim 10, wherein the substrate holder holds a single substrate.

12. The substrate processing apparatus of claim 8, further comprising a substrate holder that holds the substrate and moves the substrate up and down between a standby position above the processing tank and an immersion position in an interior of the processing tank,
wherein the controller is configured to execute:
the immersing the substrate in the ozonated water stored in the processing tank by using the substrate holder to move the substrate down from the standby position to the immersion position; and
the heating the substrate by irradiating the substrate with the light using the light irradiator while moving the substrate up and down in the ozonated water using the substrate holder.

13. The substrate processing apparatus of claim 8, further comprising a gas supply nozzle configured to supply a gas to the ozonated water stored in the processing tank,
wherein the controller is configured to execute the heating the substrate by irradiating the substrate with the light using the light irradiator while supplying the gas to the ozonated water from the gas supply nozzle.

14. The substrate processing apparatus of claim 13, wherein the gas supply nozzle is positioned in an interior of the processing tank below the substrate.

15. The substrate processing apparatus of claim 13, wherein the gas is at least one of a nitrogen gas, an oxygen gas, an ozone gas or air.

16. The substrate processing apparatus of claim 8, further comprising:
an ozonated water supply nozzle configured to supply the ozonated water to the processing tank; and
a pressurizer configured to pressurize the ozonated water at an upstream side of the ozonated water supply nozzle,
wherein the controller is configured to execute the heating the substrate by irradiating the substrate with the light using the light irradiator while supplying the ozonated water pressurized by the pressurizer from the ozonated water supply nozzle to the processing tank.

17. The substrate processing apparatus of claim 16, further comprising a throttle valve provided at a downstream side of the pressurizer in an ozonated water supply path toward the ozonated water supply nozzle and configured to adjust a pressure of the ozonated water pressurized by the pressurizer.
